(19) United States
(12) Patent Application Publication
(10) Pub. No.: US 2009/0087938 A1
(43) Pub. Date: Apr. 2, 2009

(54) Method for Manufacturing Microdevices or Integrated Circuits on Continuous Sheets

(75) Inventors: Deepak A. Ramappa, Dallas, TX (US); Richard L. Guldi, Dallas, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/863,421

(22) Filed: Sep. 28, 2007

(51) Int. Cl. H01L 21/00

(52) U.S. Cl. 438/49; 438/54; 438/57; 257/E21.001

(57) ABSTRACT

Current manufacturing of miniature or micro electronic mechanical optical chemical or biophysical devices utilizes discrete substrates holding one or more said devices. The use of discrete substrates entails several disadvantages with respect to economical manufacturing. This invention is a method of manufacturing devices using flexible carrier sheets with device substrates attached to the carrier sheet, storage/transport devices for the carrier sheet, and process tools capable of continuous processing of the carrier sheets.

### FIELD OF THE INVENTION

This invention relates to the field of manufacturing miniature or micro electronic mechanical optical chemical or biophysical devices. More particularly, this invention relates to high volume, low cost methods of manufacturing miniature or micro electronic mechanical optical chemical or biophysical devices, including integrated circuits.

### BACKGROUND OF THE INVENTION

For purposes of readability, miniature or micro electronic mechanical optical chemical or biophysical devices will be called devices during the rest of the description of this invention. Current methods of fabricating devices utilize discrete substrates, for example, silicon wafers, containing a material for one or more devices to be fabricated. These discrete substrates are processed singly or in batches through sequential fabrication steps to manufacture devices. Use of discrete substrates results in several disadvantages. Costs associated with producing substrates are a significant fraction of final costs of devices, even though a majority of substrate material is often removed in final packaged devices. Another disadvantage of the use of discrete substrates is misprocessing by incorrect or out-of-sequence fabrication operations due to human or automation errors. Another disadvantage of the use of discrete substrates is a need to match processing equipment with a size and shape of the substrates. Conversely, changing substrates requires changing most, if not all, processing equipment in a fabrication line. Another disadvantage of using discrete substrates is increased cycle time in fabrication steps performed at reduced or increased pressure or significantly reduced or increased temperature, in which substrates must undergo a delay while they are brought to processing temperature or pressure in a safe manner, for example in a load-lock chamber. Another disadvantage of the use of discrete substrates arises from customization of processing equipment for the chemical and mechanical properties of the substrate material; dissimilar substrate materials cannot be run in the same equipment, limiting the flexibility of a production line and increasing equipment costs associated with processing several types of substrates.

### SUMMARY OF THE INVENTION

This Summary is provided to comply with 37 C.F.R. §1.73, requiring a summary of the invention briefly indicating the nature and substance of the invention. It is submitted with the understanding that it will not be used to interpret or limit the scope or meaning of the claims.

This invention is a method of manufacturing miniature or micro electronic mechanical optical chemical or biophysical devices, comprising a flexible carrier sheet with device substrate material attached, storage containers for the carrier sheet, and processing tools that can perform fabrication operations on the substrates as the carrier sheet is fed through the processing tool in a continuous manner.

### DESCRIPTION OF THE VIEWS OF THE DRAWING

FIG. 1 is a view of a carrier sheet with contiguous device substrate material.

FIG. 2 is a view of a carrier sheet with discrete device substrates.

FIG. 3 is a view of a carrier sheet with discrete device substrates formed by selective deposition of substrate material.

FIG. 4 is a view of a carrier sheet with discrete device substrates formed by selective removal of substrate material.

FIG. 5 is a view of a carrier sheet with pre-made discrete device substrates attached to a carrier sheet.

FIG. 6 is a view of a carrier sheet with a leader strip.

FIG. 7 is a view of a spiral mechanical support fixture for a carrier sheet with cushioning layer.

FIG. 8 is a view of a spiral mechanical support fixture for a carrier sheet with air cushioning layer.

FIG. 9 is a view of a serpentine mechanical support fixture for a carrier sheet.

FIG. 10 is a view of a low pressure process equipment configured with single chamber.

FIG. 11 is a view of a low pressure process equipment configured with multiple process chambers.

FIG. 12 is a view of wet process equipment configured with the substrates oriented downward.

### DETAILED DESCRIPTION

The present invention is described with reference to the attached figures, wherein like reference numerals are used throughout the figures to designate similar or equivalent elements. The figures are not drawn to scale and they are provided merely to illustrate the invention. Several aspects of the invention are described below with reference to example applications for illustration. It should be understood that numerous specific details, relationships, and methods are set forth to provide a full understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

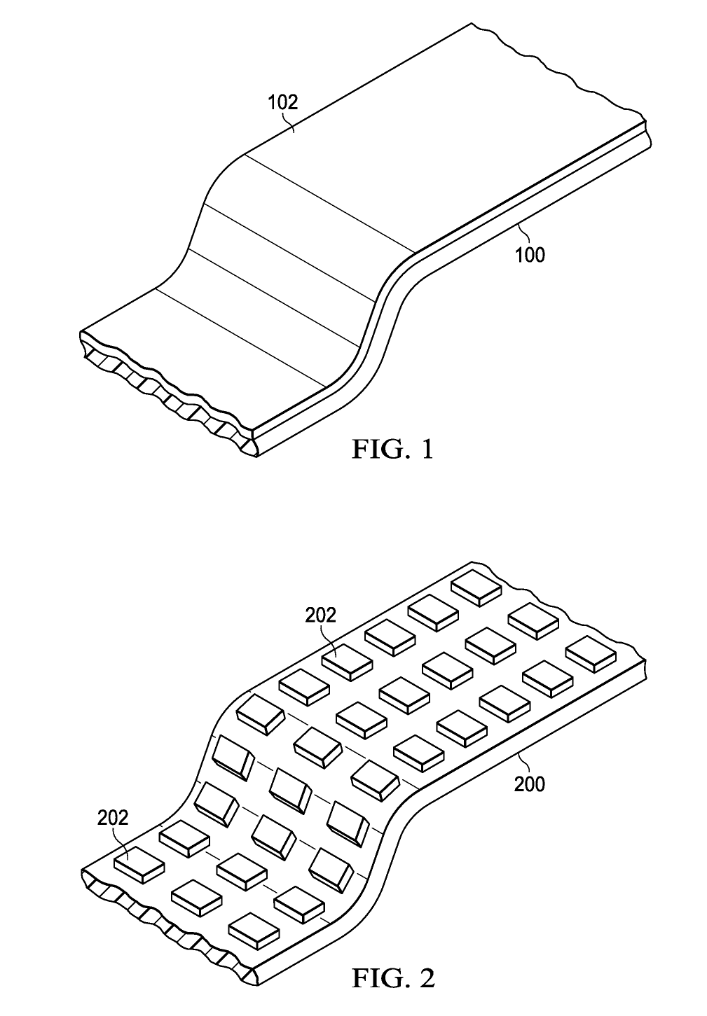

FIG. 1 is a view of a carrier sheet (100) with contiguous device substrate material (102). Carrier sheet (100) is made of a flexible material compatible with a device fabrication process and is configured as a strip to hold a contiguous sheet of device substrate material (102). In addition to product devices, additional structures to assist manufacturing operations (witness samples, test structures, alignment marks, etc.) may be fabricated on the same carrier sheet. Carrier sheet (100) is made in such a way as to facilitate removal of the device substrate material (102) at any desired point in a fabrication sequence, including an end of the fabrication sequence. Carrier sheet (100) may have perforations, indentations or other modifications or structures or multiple layers of other materials to facilitate removal of devices. Carrier sheets may be made of different materials to be compatible with different operations in the manufacturing sequence; device substrates may be transferred from one carrier sheet to another as needed to optimize efficiency and effectiveness of a manufacturing process. This is advantageous because it permits more flexibility in manufacturing operations than discrete substrates allow. Carrier sheet (100) is compatible with multiple types of substrate materials (102). This is advantageous because different devices with different substrates can be economically and efficiently run on a manufacturing line; discrete substrate dimensions are optimized for mechanical properties of the substrate material and cannot be run through the same process equipment without significant modification to process tools. Device substrate material (102) may be attached to carrier sheet (100) by various means, including, but not limited to, adhesives, thermal bonding, molecular adhesion, or direct deposition. Lengths of various carrier sheets may be adjusted to maximize efficiency and effectiveness of a manufacturing process. This is advantageous because it permits more flexibility in manufacturing logistical planning and execution than allowed by discrete substrates.

FIG. 2 is a view of a carrier sheet (200) with discrete device substrates (202). Carrier sheet (200) is made of a flexible material compatible with a fabrication process and is configured as a strip to hold a plurality of device substrates (202). Each substrate (202) may be fabricated into one or more devices. Additional substrates (202) may be added to carrier sheet (200) to assist a manufacturing process (for fabrication of witness samples, test structures, alignment marks, etc.). Carrier sheet (200) is made in such a way as to facilitate removal of device substrates (202) at any desired point in a fabrication sequence, including an end of the fabrication sequence. Carrier sheet (200) may have perforations, indentations or other modifications or structures or multiple layers of other materials to facilitate removal of device substrates (202). Carrier sheets may be made of different materials to be compatible with different operations in a manufacturing sequence; device substrates may be transferred from one carrier sheet to another as needed to optimize efficiency and effectiveness of a manufacturing process. This is advantageous because it permits more flexibility in process operations than discrete substrates allow. Carrier sheet (200) is compatible with multiple types of substrate materials (202). This is advantageous because different devices with different substrates can be economically and efficiently run on a manufacturing line; discrete substrate dimensions are optimized for mechanical properties of a substrate material and cannot be run through process equipment without significant modification to process tools. Device substrates (202) may be attached to carrier sheet (200) by various means, including, but not limited to, adhesives, thermal bonding, molecular adhesion, or direct deposition. Lengths of various said carrier sheets may be adjusted to maximize efficiency and effectiveness of the manufacturing process. This is advantageous because it permits more flexibility in manufacturing logistical planning and execution than allowed by discrete substrates.

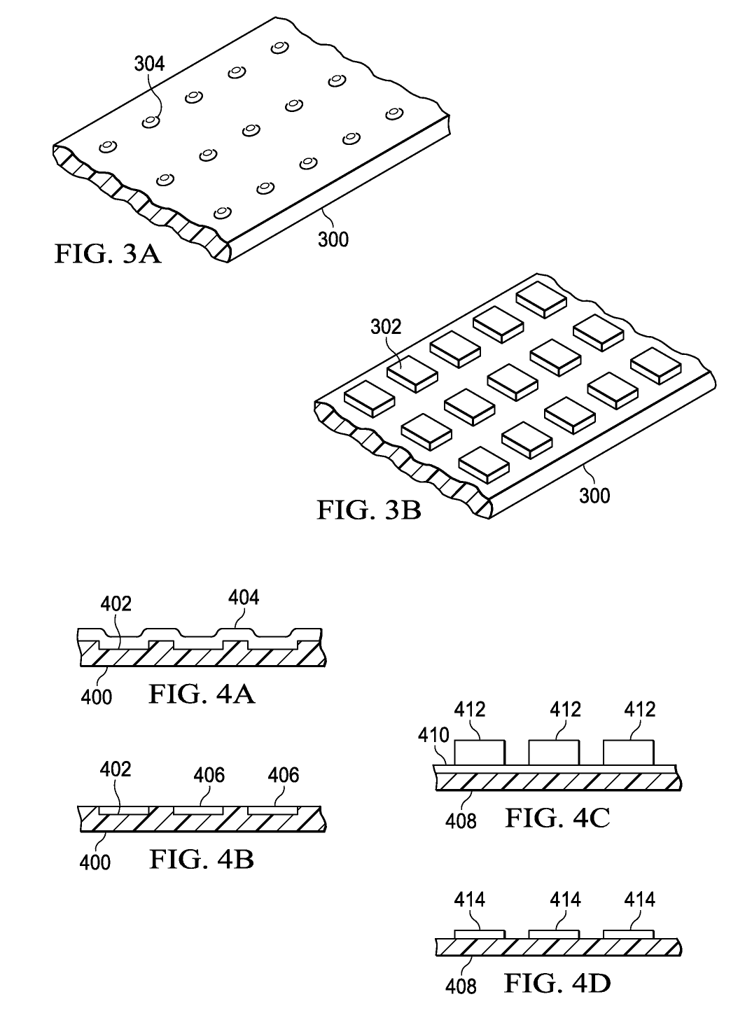

FIG. 3 is a view of a carrier sheet (300) with discrete device substrates (302) formed by selective deposition of substrate material. Carrier sheet (300) is made of a flexible material compatible with the fabrication process and is configured as a strip to hold a plurality of device substrates (302). Each substrate may be fabricated into one or more devices. Additional substrates (302) may be added to carrier sheet (300) to assist a manufacturing process (fabrication of witness samples, test structures, alignment marks, etc.). Carrier sheet (300) has affixed seeds or nuclei (304) of device substrate material. Device substrates (302) are formed on carrier sheet (300) by growing or depositing substrate material on seeds or nuclei (304). Carrier sheet (300) is made in such a way as to facilitate the removal of device substrates (302) at any desired point in a fabrication sequence, including an end of the fabrication sequence. Carrier sheet (300) may have perforations, indentations or other modifications or structures or multiple layers of other materials to facilitate removal of device substrates (302). Carrier sheets may be made of different materials to be compatible with different operations in a manufacturing sequence; device substrates may be transferred from one carrier sheet to another as needed to optimize efficiency and effectiveness of a manufacturing process. This is advantageous because it permits more flexibility in process operations than discrete substrates allow. Carrier sheet (300) is compatible with multiple types of substrate material seeds or nuclei (304). This is advantageous because different devices with different substrates can be economically and efficiently run on a manufacturing line; discrete substrate dimensions are optimized for mechanical properties of a substrate material and cannot be run through process equipment without significant modification to process tools. Device substrate material seeds or nuclei (302) may be attached to carrier sheet (300) by various means, including, but not limited to, adhesives, thermal bonding, molecular adhesion, or direct deposition. Lengths of various said carrier sheets may be adjusted to maximize efficiency and effectiveness of a manufacturing process. This is advantageous because it permits more flexibility in manufacturing logistical planning and execution than allowed by discrete substrates.

FIG. 4 is a view of a carrier sheet with discrete device substrates formed by selective removal of substrate material. Carrier sheet is made of a flexible material compatible with a fabrication process and is configured as a strip to hold a plurality of device substrates. Each substrate may be fabricated into one or more devices. Additional substrates may be added to carrier sheet to assist the manufacturing process (fabrication of witness samples, test structures, alignment marks, etc.). In one embodiment, depicted in FIGS. 4A and 4B, a carrier sheet (400) has recesses (402) in a top surface where device substrates are desired. Device substrate material (404) is deposited on carrier sheet (400) in a manner compatible with fabrication of devices. In this embodiment, device substrate material (404) is removed from the top surface of carrier sheet (400) leaving device substrates (406) in recesses (402). In another embodiment, depicted in FIGS. 4C and 4D, a carrier sheet (408) has affixed to it a device substrate material (410). Unwanted substrate material is removed by any of several methods, including, but not limited to, mechanical machining, electrochemical machining, etching, polishing or ablation. Areas for discrete device substrates may be defined by masking material (412), in a manner including, but not limited to, printing, photolithography, or pattern transfer, to facilitate removal of unwanted substrate material. Remaining substrate material forms device substrates (414). In both embodiments depicted in FIG. 4, carrier sheets are made in such a way as to facilitate removal of device substrates at any desired point in a fabrication sequence, including an end of the fabrication sequence. In both embodiments depicted in FIG. 4, carrier sheets may have perforations, indentations or other modifications or structures or multiple layers of other materials to facilitate removal of device substrates. In both embodiments depicted in FIG. 4, carrier sheets may be made of different materials to be compatible with different operations in a manufacturing sequence; device substrates may be transferred from one carrier sheet to another as needed to optimize efficiency and effectiveness of a manufacturing process. This is advantageous because it permits more flexibility in process operations than discrete substrates allow. In both embodiments depicted in FIG. 4, carrier sheets are compatible with multiple types of substrate materials. This is advantageous because different devices with different substrates can be economically and efficiently run on a manufacturing line; discrete substrate dimensions are optimized for mechanical properties of substrate material and cannot be run through process equipment without significant modification to process tools. In both embodiments depicted in FIG. 4, device substrate materials may be attached to carrier sheets by various means, including, but not limited to, adhesives, thermal bonding, molecular adhesion, or direct deposition. In both embodiments depicted in FIG. 4, lengths of various said carrier sheets may be adjusted to maximize efficiency and effectiveness of a manufacturing process. This is advantageous because it permits more flexibility in manufacturing logistical planning and execution than allowed by discrete substrates.

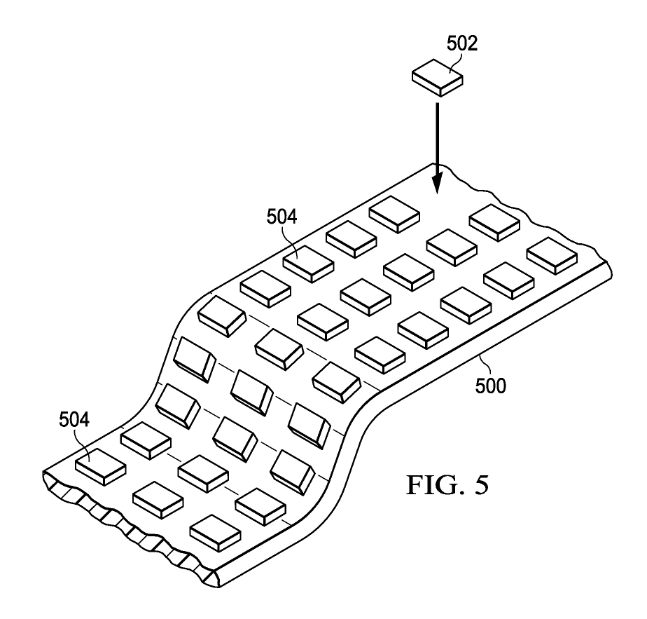

FIG. 5 is a view of a carrier sheet (500) with a plurality of pre-made discrete device substrates (502) attached to a carrier sheet. Carrier sheet (500) is made of a flexible material compatible with the fabrication process and is configured as a strip to hold a plurality of device substrates (504). Each substrate (504) may be fabricated into one or more devices. Additional substrates (504) may be added to carrier sheet to assist the manufacturing process (fabrication of witness samples, test structures, alignment marks, etc.). Pre-made device substrates (502) may be partially fabricated devices or unprocessed substrate material. Carrier sheet (500) is made in such a way as to facilitate removal of device substrates (504) at any desired point in a fabrication sequence, including an end of the fabrication sequence. Carrier sheet (500) may have perforations, indentations or other modifications or structures or multiple layers of other materials to facilitate removal of device substrates (504). Carrier sheets (500) may be made of different materials to be compatible with different operations in a manufacturing sequence; device substrates may be transferred from one carrier sheet to another as needed to optimize efficiency and effectiveness of a manufacturing process. This is advantageous because it permits more flexibility in process operations than discrete substrates allow. Carrier sheet (500) is compatible with multiple types of substrates (502). This is advantageous because different devices with different substrates can be economically and efficiently run on a manufacturing line; discrete substrate dimensions are optimized for mechanical properties of substrate material and cannot be run through process equipment without significant modification to process tools. Device substrates (502) may be attached to carrier sheet (500) by various means, including, but not limited to, adhesives, thermal bonding, molecular adhesion, or direct deposition. Lengths of various carrier sheets (500) may be adjusted to maximize efficiency and effectiveness of a manufacturing process. This is advantageous because it permits more flexibility in manufacturing logistical planning and execution than allowed by discrete substrates.

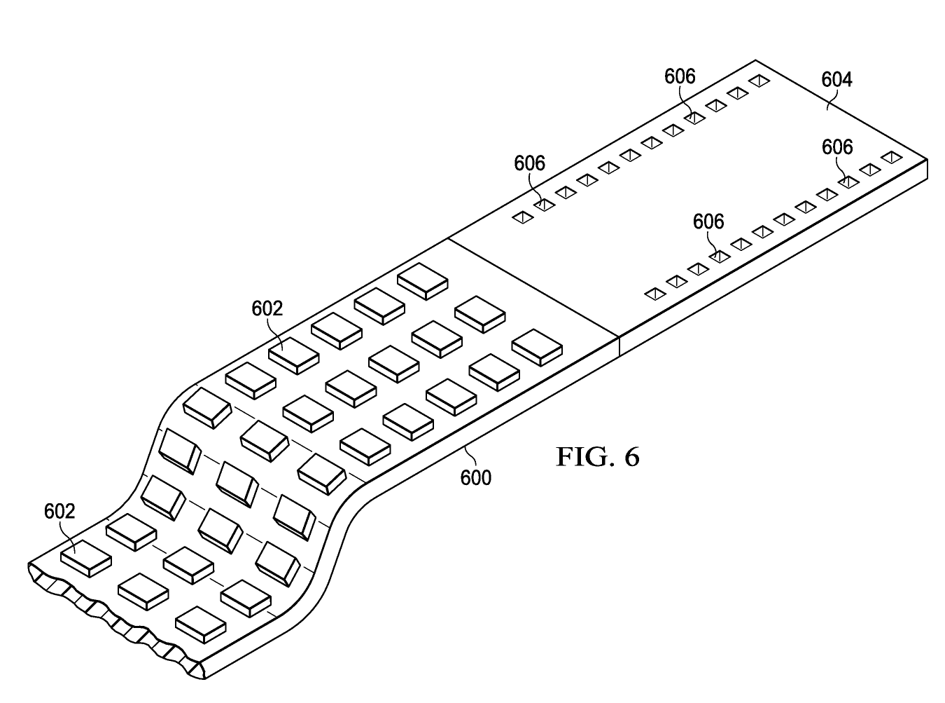

FIG. 6 is a view of a carrier sheet (600) with device substrates (602) with a leader strip (604). Any embodiments of said carrier sheets mentioned above may be enhanced by adding a leader strip (604) to facilitate feeding carrier sheet (600) through fabrication equipment. In a similar manner, any embodiments of said carrier sheets mentioned above may be enhanced by adding a trailer strip (not shown for clarity) to facilitate feeding carrier sheet (600) through fabrication equipment. Leader strip (604) and trailer strip may have perforations, recesses, raised areas, or other modifications (606) to facilitate feeding carrier sheet (600) through fabrication equipment. Leader strip (604) and trailer strip may be made of a same material as carrier strip (600) or of a different material, to optimize efficiency and effectiveness of a manufacturing process. Leader strip (604) and trailer strip may be permanently attached to carrier sheet (600) or may be detachable. Leader strip (604) and trailer strip may be reusable or single-use.

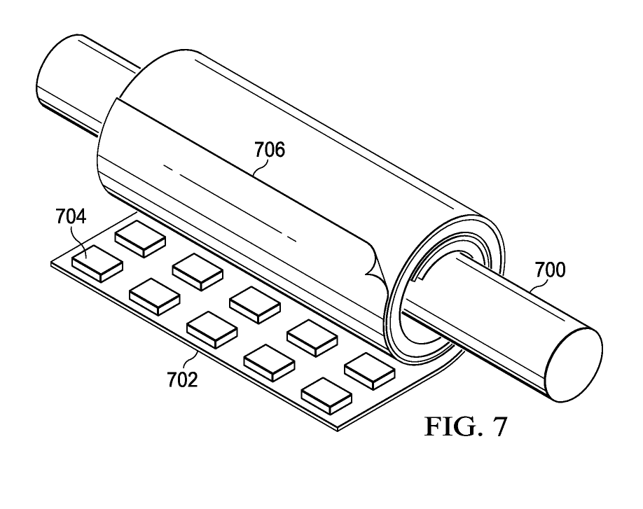

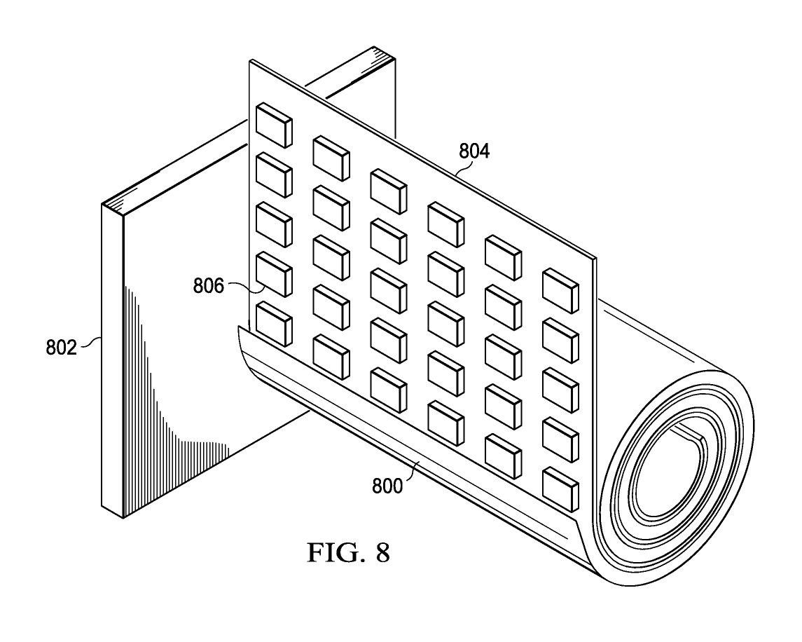

FIG. 7 is a view of a spiral mechanical support fixture for a carrier sheet with cushioning layer. A spindle (700) serves as mechanical support for a carrier sheet as described above (702) with devices as described above (704) at any stage of fabrication attached. A cushion sheet (706) with a property of protecting said devices (704) on carrier sheet (702) is positioned on a surface of carrier sheet (702) over devices (704) and carrier sheet (702) and cushion sheet (706) are wound together onto spindle (700). Said wound configuration is advantageous for storing and transporting carrier sheet (702) and for interfacing carrier sheet (702) with processing equipment because it minimizes space required to accommodate carrier sheet (702). Spindle (700) with wound carrier sheet (702) and cushion sheet (706) may be surrounded by a rigid cover for protection.

FIG. 8 is a view of a spiral mechanical support fixture for a carrier sheet with an air cushioning layer. A spiral guide (800) is mechanically supported by a framework (802) on one or both ends. A carrier sheet (804) as described above with devices as described above (806) at any stage of fabrication attached is inserted into the spiral guide (800). Spiral guide (800) is configured so that a front surface of devices (806) do not contact spiral guide (800) during insertion or extraction of carrier sheet (804), or during storage and transport of carrier sheet (804). Said spiral configuration is advantageous for storing and transporting carrier sheet (804) and for interfacing carrier sheet (804) with processing equipment because it minimizes space required to accommodate carrier sheet (804).

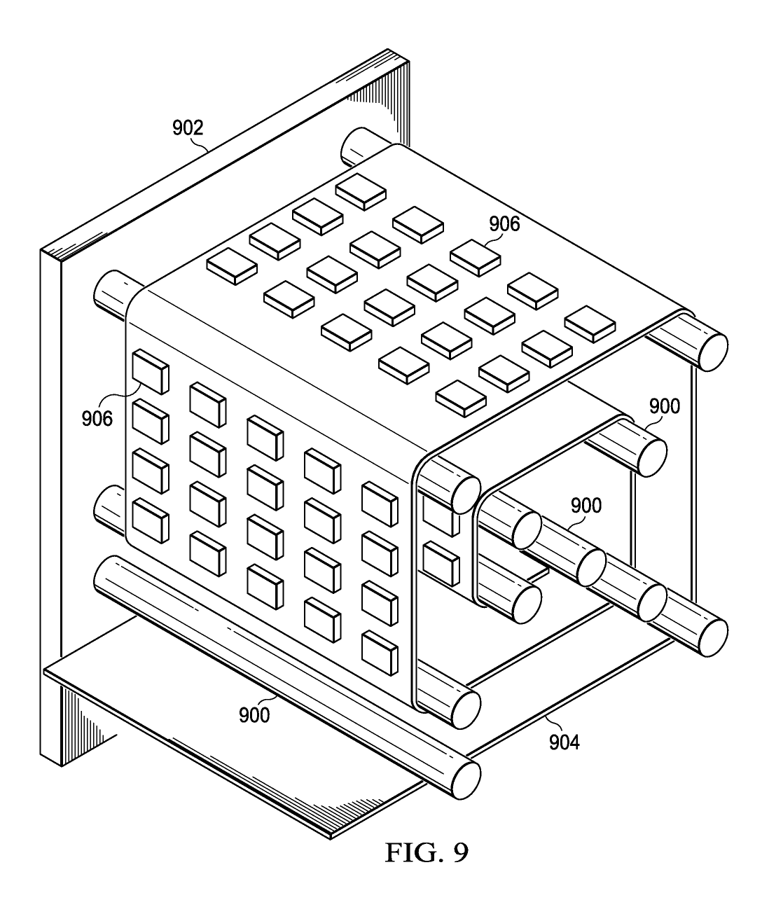

FIG. 9 is a view of a segmented mechanical support fixture for a carrier sheet. Winding rods (900) are arrayed and supported by a framework (902). A carrier sheet as described above (904) with devices as described above (906) at any stage of fabrication attached is wound by a suitable mechanism onto winding rods (900). Carrier sheet (904) is wound onto winding rods (900) in a manner that devices (906) attached to carrier sheet (904) are not contacted by winding rods (900). Said wound configuration is advantageous for storing and transporting carrier sheet (904) and for interfacing carrier sheet (904) with processing equipment because it minimizes space required to accommodate carrier sheet (904). Winding rods (900) with wound carrier sheet (904) may be surrounded by a rigid cover for protection.

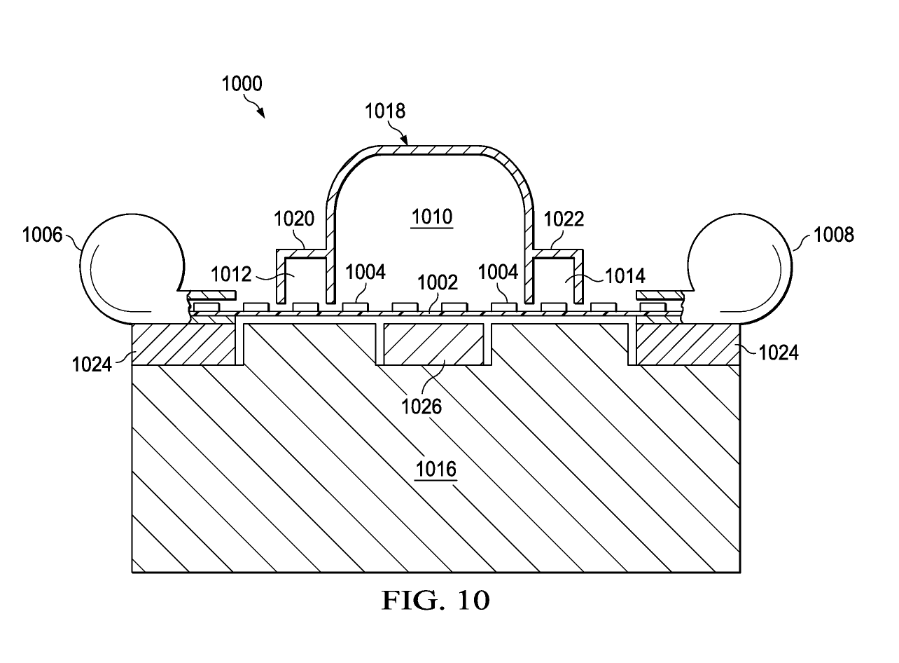

FIG. 10 is a view of a process tool (1000) configured with a single chamber. A carrier sheet (1002) as described above with devices as described above (1004) at any stage of fabrication attached is fed out of a delivery storage container (1006) through process tool (1000) into a takeup storage container (1008). Process tool (1000) includes a process chamber (1010) flanked by an input chamber (1012) and an output chamber (1014), all mounted on a console (1016). Process chamber (1010) is contained by a process chamber vessel (1018) which is configured to accept carrier sheet (1002) while maintaining desired process conditions such as temperature, pressure and gas flows. Input chamber (1012) is contained by an input chamber vessel (1020) which is configured to accept carrier sheet (1002) from delivery container (1006) and feed carrier sheet (1002) into process chamber (1010) while isolating an ambient in process chamber (1010) from an ambient external to process tool (1000). In a similar manner, output chamber (1014) is contained by an output chamber vessel (1022) which is configured to accept carrier sheet (1002) from process chamber (1010) and feed carrier sheet (1002) into takeup container (1008) while isolating the ambient in process chamber (1010) from the ambient external to the process tool (1000). This is advantageous because use of continuous flow input and output chambers increases process throughput compared to batch load locks used with discrete substrates. Delivery container (1006) and takeup container (1006) are supported on process tool (1000) by container docking fixtures (1024). Docking fixtures (1024) are configured to continuously feed carrier strips from sequential delivery containers (1006) without interrupting a manufacturing process. In a similar manner, docking fixtures are configured to feed sequential carrier strips to appropriate takeup containers without interrupting the manufacturing process. This is advantageous because it reduces cycle time compared to batch processing of discrete substrates. Devices (1002) are maintained at a desired process temperature by a temperature regulated chuck (1026).

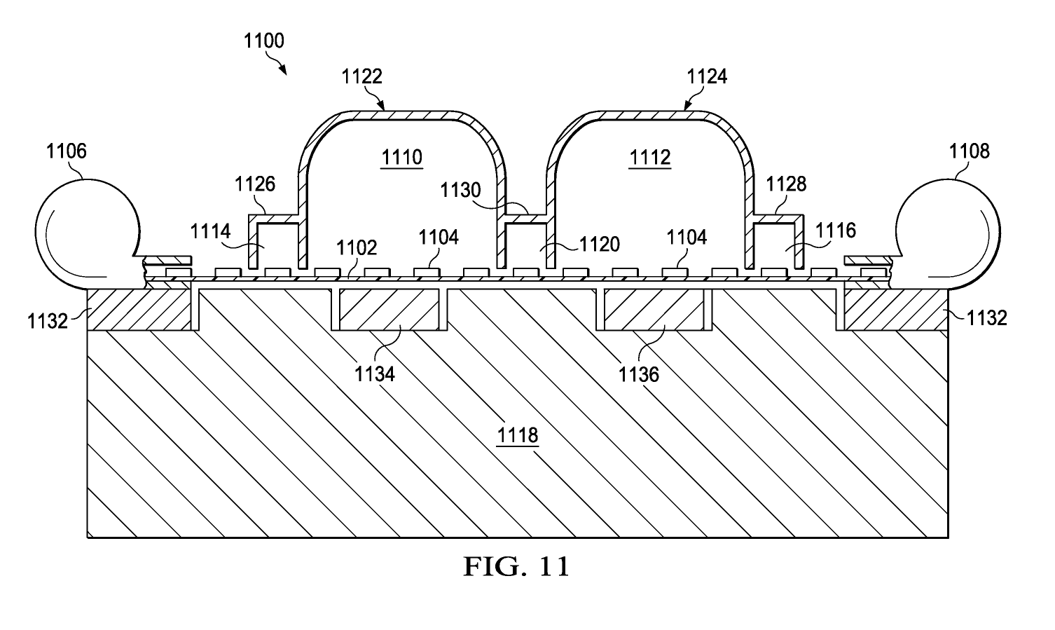

FIG. 11 is a view of a process tool (1100) configured with a plurality of process chambers. A carrier sheet (1102) as described above with devices as described above (1104) at any stage of fabrication attached is fed out of a delivery storage container (1106) through process tool (1100) into a takeup storage container (1108). Process tool (1100) includes a plurality of process chambers (1110, 1112, etc.) flanked by an input chamber (1114) and an output chamber (1116), all mounted on a console (1118). Between each sequential pair of process chambers (for example first process chamber (1110) and second process chamber (1112) is configured a transfer chamber (1120). First process chamber (1110) is contained by a process chamber vessel (1122) which is configured to accept carrier sheet (1102) while maintaining desired process conditions such as temperature, pressure and gas flows. Second process chamber (1112) is contained by a process chamber vessel (1124) which is configured to accept said carrier sheet (1102) while maintaining desired process conditions such as temperature, pressure and gas flows. Additional process chambers may be sequentially configured in a similar manner on process tool (1100) as needed. This is advantageous because configuring sequential chambers on a single process tool improves cycle time and reduces misprocessing due to human or automation errors compared with single chamber or cluster tools used for discrete substrates. Input chamber (1114) is contained by an input chamber vessel (1126) which is configured to accept carrier sheet (1102) from delivery container (1106) and feed carrier sheet (1102) into first process chamber (1110) while isolating an ambient in first process chamber (1110) from an ambient external to the process tool (1100). In a similar manner, output chamber (1116) is contained by an output chamber vessel (1128) which is configured to accept carrier sheet (1102) from the last of said process chambers and feed carrier sheet (1102) into takeup container (1108) while isolating an ambient in the last process chamber from the ambient external to process tool (1100). Each transfer chamber (1120) is contained by a transfer chamber housing (1130) which is configured to transfer carrier sheet (1102) between the appropriate process chambers (1110, 1112, etc.) while isolating ambients in adjacent process chambers from each other. This is advantageous because use of continuous flow input, output and transfer chambers increases process throughput compared to batch load locks used with discrete substrates. Delivery container (1106) and takeup container (1108) are supported on process tool (1100) by container docking fixtures (1132). Docking fixtures (1132) are configured to continuously feed carrier strips from sequential delivery containers (1106) without interrupting a manufacturing process. In a similar manner, docking fixtures are configured to feed sequential carrier strips to appropriate takeup containers without interrupting the manufacturing process. This is advantageous because it reduces cycle time compared to batch processing of discrete substrates. Devices (1104) in each process chamber are maintained at the desired process temperature by temperature regulated chucks (1034, 1136, etc.).

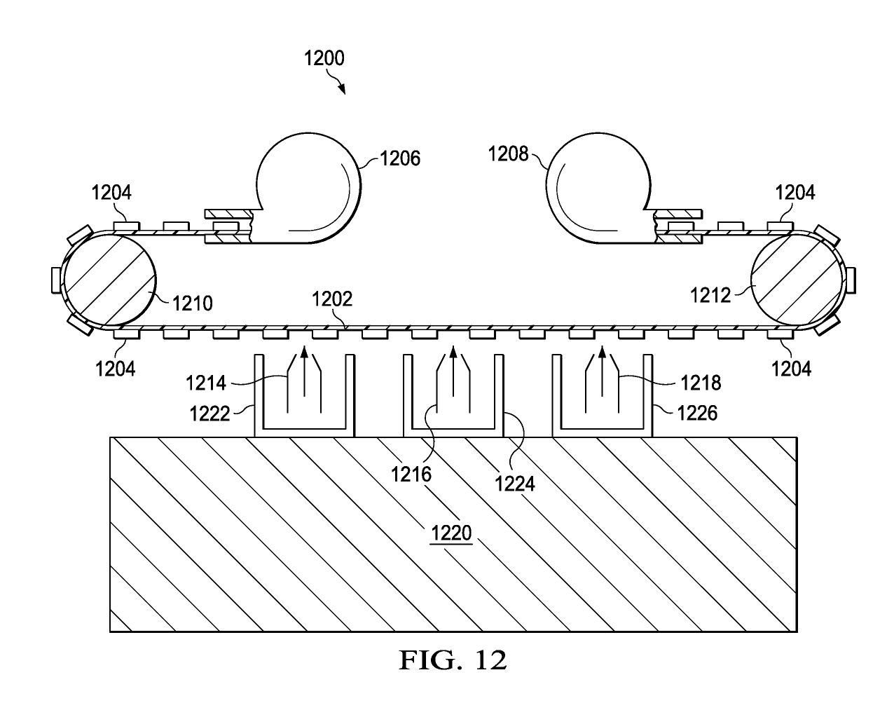

FIG. 12 is a view of a process tool (1200) configured with substrates oriented downward. A carrier sheet (1202) as described above with devices as described above (1204) at any stage of fabrication attached is fed out of a delivery storage container (1206) through process tool (1200) into a takeup storage container (1208). Carrier sheet (1202) is oriented by delivery orienting mechanism (1210) and takeup orienting mechanism (1212) to position devices (1204) in an optimum orientation for process effectiveness. Process tool (1200) includes multiple process sites (1214, 1216, 1218, etc.), all mounted on a console (1220). Each process site (1214, 1216, 1218, etc.) is contained in appropriate housing (1222, 1224, 1226, etc.) to control process chemicals and isolate process conditions in each site for adjacent sites.

What is claimed is:

1. A method of manufacturing miniature or micro electronic mechanical optical chemical or biophysical devices comprising the steps of:
providing a carrier sheet comprising:
a flexible material, configured as a strip;
attaching substrate material for said devices to a top surface of said carrier sheet;
fabricating said devices in said substrate material; and
removing said devices from said carrier sheet.

2. The method of claim 1, wherein said carrier sheet further comprises features which facilitate removal of devices.

3. The method of claim 1, wherein the step of fabricating said devices in said substrate material further comprises the steps of:
fabricating said devices partly through a fabrication process sequence;
providing a second carrier sheet;
removing said devices from said carrier sheet of claim 1;
attaching said devices to said second carrier sheet; and
fabricating said devices through a remainder of said fabrication process sequence.

4. The method of claim 1, further comprising the steps of:
providing a third carrier sheet, configured as a strip, wherein a length of the third carrier sheet is different from a length of said carrier sheet of claim 1;
attaching a second substrate material for said devices to a top surface of said third carrier sheet;
fabricating said devices in said second substrate material; and
removing said devices from said third carrier sheet.

5. The method of claim 1, wherein said substrate material is comprised of a plurality of discrete pieces.

6. The method of claim 5, wherein a plurality of said devices is fabricated in each said discrete piece of said substrate material.

7. The method of claim 5, wherein the step of attaching substrate material for said devices to a top surface of said carrier sheet further comprises the steps of:
depositing said substrate material on a top surface of said carrier sheet; and
selectively removing a portion of said substrate material.

8. The method of claim 1, wherein the step of providing a carrier sheet further comprises the step of attaching a leader strip to a leading end of said carrier sheet.

9. The method of claim 1, wherein the step of providing a carrier sheet further comprises the step of attaching a trailer strip to a trailing end of said carrier sheet.

10. The method of claim 1, wherein the step of fabricating said devices in said substrate material further comprises the steps of:
providing a storage container for said carrier sheet;
feeding said carrier sheet into said storage container; and
extracting said carrier sheet from said storage container.

11. The method of claim 1, wherein the step of fabricating said devices in said substrate material further comprises the steps of:
providing a processing tool, which is capable of performing a fabrication operation on said devices on sequential portions of said carrier sheet in a continuous manner;
feeding said carrier sheet into said processing tool in a continuous manner;
performing said fabrication operation on said devices on sequential portions of said carrier sheet in said processing tool in a continuous manner; and
extracting said carrier sheet from said processing tool in a continuous manner.

12. The method of claim 11, further comprising the steps of:
feeding said carrier sheet into said storage container of claim 10;
attaching said storage container to said processing tool;
feeding said carrier sheet from said storage container into said processing tool;
providing a second storage container; and
extracting said carrier sheet from said processing tool into said second storage container.

13. The method of claim 11, wherein
the step of providing a processing tool further comprises the steps of:
providing a processing chamber, wherein said fabrication operation is performed;
providing an input chamber adjacent to said processing chamber, wherein said carrier sheet is fed through the input chamber into said processing chamber, whereby an ambient in said processing chamber is isolated from an ambient external to said processing chamber; and
providing an output chamber adjacent to said processing chamber, wherein said carrier sheet is fed from said processing chamber through the output chamber, whereby an ambient in said processing chamber is isolated from an ambient external to said processing chamber;
and the step of feeding said carrier sheet into said processing tool in a continuous manner further comprises the step of feeding said carrier sheet through said input chamber into said processing chamber in a continuous manner;
and the step of extracting said carrier sheet from said processing tool in a continuous manner further comprises the step of extracting said carrier sheet from said processing chamber through said output chamber in a continuous manner.

14. The method of claim 1, further comprising the steps of:
providing a second processing tool, which is capable of performing a second and third fabrication operations on said devices on sequential portions of said carrier sheet in a continuous manner, comprising the steps:
providing a second processing chamber, wherein a second fabrication operation is performed;
providing a third processing chamber, wherein a third fabrication operation is performed;
providing an second input chamber adjacent to said second processing chamber, wherein said carrier sheet is fed through the second input chamber into said second processing chamber, whereby an ambient in said second processing chamber is isolated from an ambient external to said second processing chamber;
providing a transfer chamber between said second processing chamber and said third processing chamber, wherein said carrier sheet is fed through the transfer chamber from said second processing chamber into said third processing chamber, whereby an ambient in said second processing chamber is isolated from an ambient in said third processing chamber;
providing a second output chamber adjacent to said third processing chamber, wherein said carrier sheet is fed from said third processing chamber through the second output chamber, whereby an ambient in said third processing chamber is isolated from an ambient external to said third processing chamber;
feeding said carrier sheet through said second input chamber into said second processing chamber in a continuous manner;
performing said second and third fabrication operations on said devices on sequential portions of said carrier sheet in a continuous manner, comprising the steps:
performing said second fabrication operation on said devices on sequential portions of said carrier sheet in said second processing chamber in a continuous manner;
feeding said carrier sheet from said second processing chamber through said transfer chamber into said third processing chamber; and
performing said third fabrication operation on said devices on sequential portions of said carrier sheet in said third processing chamber in a continuous manner; and
extracting said carrier sheet from said third processing chamber through said second output chamber in a continuous manner.

15. The method of claim 11, further comprising the steps of:
providing a fourth carrier sheet comprising a flexible material, configured as a strip;
attaching a third substrate material for said devices to a top surface of said fourth carrier sheet;
feeding said fourth carrier sheet into said processing tool in a continuous manner, whereby no time delay is experienced between a trailing edge of said carrier sheet of claim 1 entering said processing tool and a leading edge of said fourth carrier sheet entering said processing tool;
performing said fabrication operation on said devices on sequential portions of said fourth carrier sheet in a continuous manner; and
extracting said fourth carrier sheet from said processing tool in a continuous manner.

16. The method of claim 11, further comprising the steps of:
providing an orienting mechanism adjacent to said input chamber, whereby said carrier sheet may be oriented in a desired orientation; and
orienting said carrier sheet in a desired orientation before said carrier sheet is fed into said processing tool.
